(19) United States
(12) Patent Application Publication
(10) Pub. No.: US 2009/0232319 A1
(43) Pub. Date: Sep. 17, 2009

(54) AUDIO PLAYING APPARATUS AND METHOD THEREOF

(76) Inventor: Peng-Feng Kao, Taipei County (TW)

Correspondence Address: Muncy, Geissler, Olds & Lowe, PLLC, P.O. BOX 1364, FAIRFAX, VA, 22038-1364, US

(21) Appl. No.: 12/400,374

(22) Filed: Mar. 9, 2009

(30) Foreign Application Priority Data
Mar. 14, 2008 (TW) 097109141

(51) Int. Cl. H03G 3/20

(52) U.S. Cl. 381/57

(57) ABSTRACT

The invention discloses an audio playing apparatus. The audio playing apparatus has a sound detecting module, a transforming module, a controlling module and an output module. The sound detecting module is used for acquiring a sound of background sounds and generating a background sound signal. The transforming module is coupled to the sound detecting module for transforming the background sound signal to a background sound value. The controlling module is coupled to the transforming module for adjusting the volume of an audio signal according to a predetermined manner and the background sound value and generating an output signal. The output module is coupled to the controlling module for playing the output signal.

### CROSS REFERENCE TO RELATED APPLICATIONS

This Non-provisional application claims priority under 35 U.S.C. §119(a) on Patent Application No(s). 97109141, filed in Taiwan, Republic of China on Mar. 14, 2008, the entire contents of which are hereby incorporated by reference.

### BACKGROUND OF THE INVENTION

1. Field of the Invention

The invention relates to an audio playing apparatus, and more particularly to an audio playing apparatus for auto-adjusting the volume according to background sounds.

2. Description of the Related Art

Conventionally, audio playing apparatuses play sounds with a volume which is preset by a user. As a result, a suitable volume played by the audio playing apparatus in a quiet environment would be too soft to be heard clearly by a user in a noisy environment. Conversely, a suitable volume played by the audio playing apparatus for a user in a noisy environment would be too loud in a quiet environment. Thus, causing inconvenience to users.

Specifically, users must constantly adjust the volume of audio playing apparatuses for different background sound environments. Thus, automatic adjusting volume control is an important issue for audio playing devices and the like.

### BRIEF SUMMARY OF INVENTION

Provided is an audio playing apparatus, comprising a sound detecting module, a transforming module, a controlling module and an output module. Wherein the sound detecting module is used for acquiring a sound of background sounds and generating a background sound signal, the transforming module is coupled to the sound detecting module for transforming background sounds sound signal to a background sound value, and the controlling module is coupled to the transforming module for adjusting the volume of an audio signal according to a predetermined manner and the background sounds sound value and generating an output signal. The output module is coupled to the controlling module for playing the output signal.

Provided is also an audio playing method, comprising acquiring a sound of background sounds and generating a background sound signal, transforming the background sounds sound signal to generate a background sound value, adjusting the volume of an audio signal according to a predetermined manner and background sound value to generate an output signal, and playing the output signal.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is an illustrative diagram of the audio playing apparatus in the present invention;

FIG. 2A is an illustrative diagram of the transforming module of the audio playing apparatus in the present invention;

FIG. 2B is an illustrative diagram of the controlling module of the audio playing apparatus in the present invention;

FIG. 2C is an illustrative diagram of the output module of the audio playing apparatus in the present invention;

FIG. 3 is a flowchart illustrating the audio playing method in the present invention;

FIG. 4A is a flowchart illustrating the step S32 of the audio playing method in the present invention;

FIG. 4B is a flowchart illustrating one embodiment of the step S34 of the audio playing method in the present invention;

FIG. 4C is a flowchart illustrating another embodiment of the step S34 of the audio playing method in the present invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

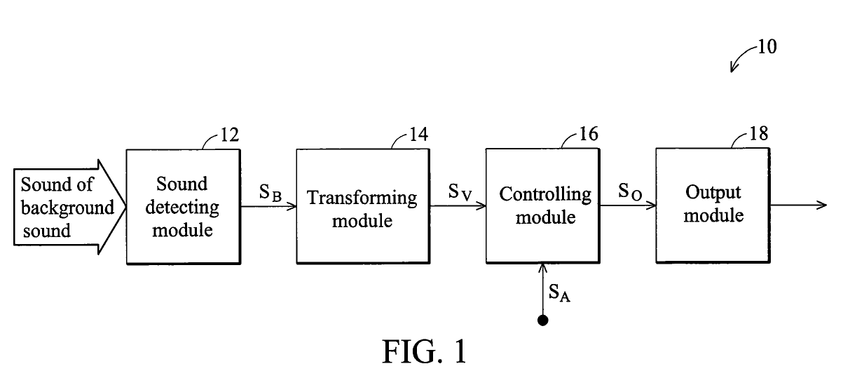

Referring to FIG. 1, an illustrative diagram of the audio playing apparatus 10 in the present invention is shown. As shown in FIG. 1, the present invention is an audio playing apparatus 10, comprising a sound detecting module 12, a transforming module 14, a controlling module 16, and an output module 18. The sound detecting module 12 is used for acquiring a sound of background sounds and generating a background sound signal S_{B}. In one embodiment, the detecting module 12 is a sensor used for acquiring the sound of background sounds from the background sounds and further generating a background sound signal S_{B}. The transforming module 14 is coupled to the sound detecting module 12 and transforms the background sound signal S_{B} to a background sound value S_{V}. The controlling module 16 is coupled to the transforming module 14 and is used for adjusting the volume of an audio signal S_{A} according to a predetermined manner and the background sound value S_{V} and generating an output signal S_{O}. The output module 18 is coupled to the controlling module 16 and used for playing the output signal S_{O}.

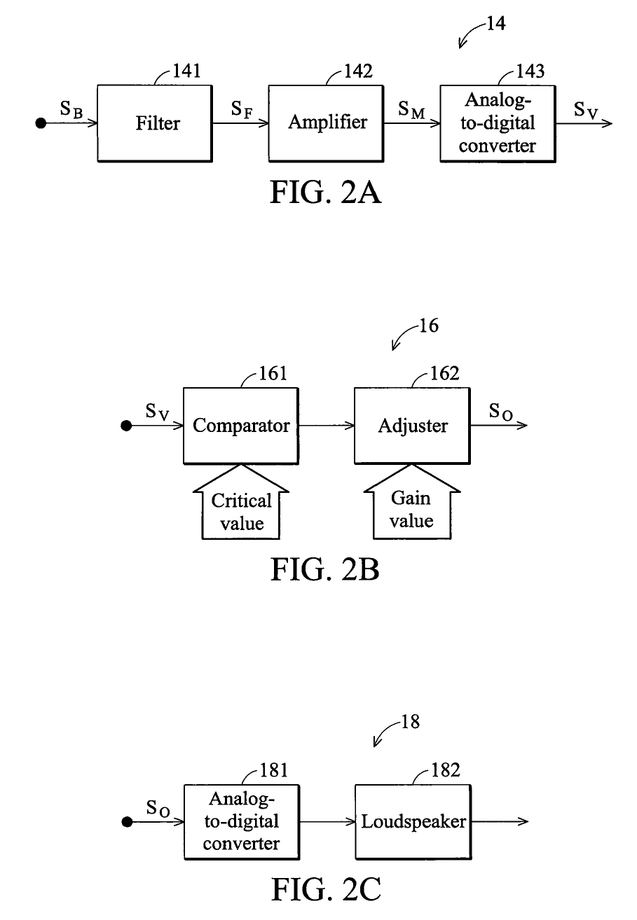

Referring to FIG. 2A, an illustrative diagram of the transforming module 14 of the audio playing apparatus 10 in the present invention is shown. As shown in FIG. 2A, the transforming module 14 comprises a filter 141, an amplifier 142 and an analog-to-digital converter 143. The filter 141 is used for filtering the sound of the background sound signal S_{B} to generate a filtering signal S_{F}. The amplifier 142 is coupled to the filter 141 for amplifying the filtering signal S_{F} to generate an amplifying signal S_{M}. The analog-to-digital converter 143 is coupled to the amplifier 142 for converting the amplifying signal S_{M} to generate the background sound value S_{V}.

In one embodiment, the predetermined manner is to predetermine a gain value. The controlling module 16 is used for adjusting the volume of the audio signal S_{A} according to the background sound value and the gain value and generating the output signal S_{O}. In addition, in another embodiment, the predetermined manner is to predetermine a critical value and a gain value, and the controlling module 16 determines whether the background sound value S_{V} is larger than the critical value. If the determination is yes, the controlling module 16 adjusts the volume of the audio signal S_{A} according to the gain value and generates the output signal S_{O}.

Referring to FIG. 2B, an illustrative diagram of the controlling module 18 of the audio playing apparatus 10 in the present invention is shown. As shown in FIG. 2B, the controlling module 16 comprises a comparator 161 and an adjuster 162. The comparator 161 is used for comparing the background sound value S_{V} with the critical value and generating a comparative result C₁. The adjuster 162 is coupled to the comparator 161 and adjusts the audio signal S_{A} according to the comparative result C₁ and the gain value. The adjuster 162 adjusts the audio signal S_{A} according to the gain value when the background sound value S_{V} is larger than the critical value.

In another embodiment, the controlling module 16 comprises a reference table, and the predetermined manner is to consult the reference table. The reference table comprises a plurality of background sound values S_{V} and a plurality of their respective corresponding gain values. In one embodiment, the controlling module 16 consults the reference table to adjust the volume of the audio signal S_{A}, and generates the output signal S_{O}.

Referring to FIG. 2C, an illustrative diagram of the output module 18 of the audio playing apparatus 10 in the present invention is shown. As shown in FIG. 2C, the output module 18 comprises a digital-to-analog converter 181 and a loudspeaker 182. The digital-to-analog converter 181 is used for converting the output signal from digital mode to an analog mode. The loudspeaker 182 is coupled to the digital-to-analog convert and used for playing the output signal S_{O} in analog mode.

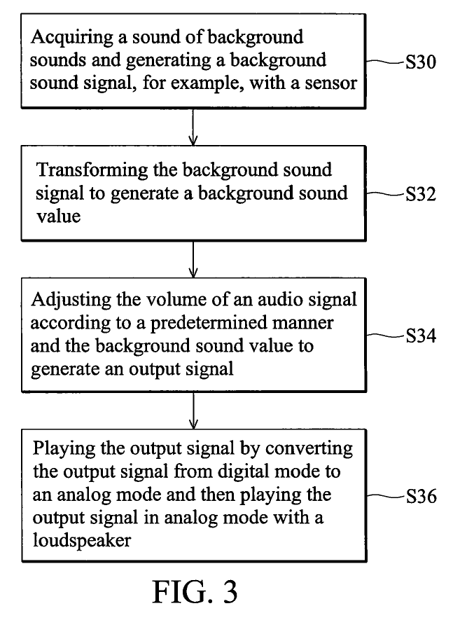

Referring to FIG. 3, a flowchart illustrating the audio playing method in the present invention is shown. As shown in FIG. 3, one of the embodiments of the present invention is to disclose an audio playing method, which comprises:
S30, acquiring a sound of background sounds and generating a background sound signal, for example, with a sensor.
Step 32, transforming the background sound signal to generate a background sound value;
Step 34, adjusting the volume of an audio signal according to a predetermined manner and the background sound value to generate an output signal; and
Step 36, playing the output signal by converting the output signal from digital mode to an analog mode and then playing the output signal in analog mode with a loudspeaker

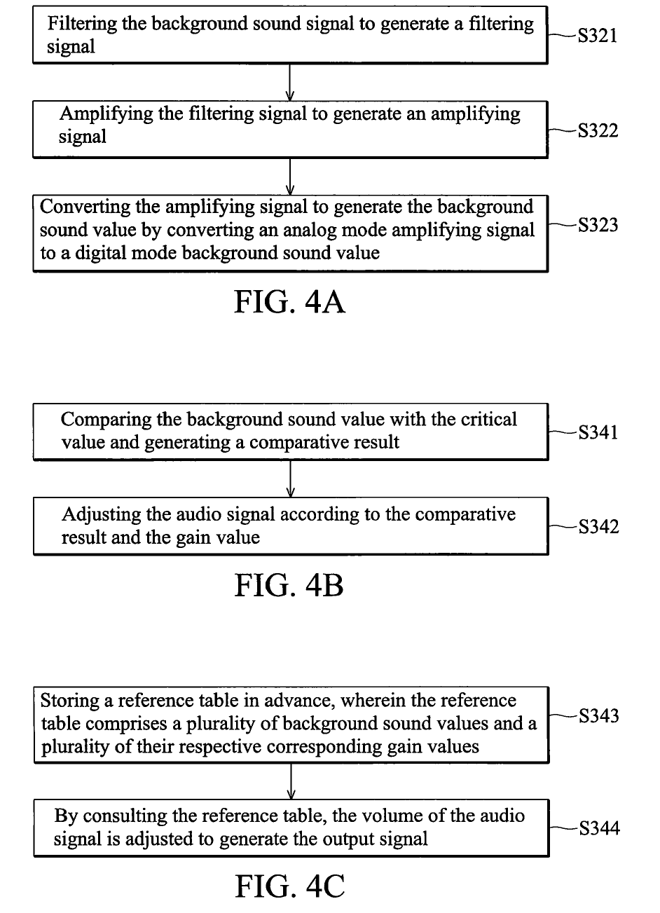

Referring to FIG. 4A, a flowchart illustrating the step S32 of the audio playing method in the present invention is shown. As shown in FIG. 4A, the step S32 further comprises:
Step 321, filtering the background sound signal to generate a filtering signal;
Step 322, amplifying the filtering signal to generate an amplifying signal; and
Step 323, converting the amplifying signal to generate the background sound value by converting an analog mode amplifying signal to a digital mode background sound value.

In one embodiment, the predetermined manner in the step S34 is to predetermine a gain value, and the step S34 is to adjust the volume of the audio signal according to the background sound value and the gain value to generate the output signal. In another embodiment, the predetermined manner in the step S34 is to predetermine a critical value and a gain value, and the step S34 determines whether the background sound value is larger than the critical value, and if yes, it adjusts the volume of the audio signal according to the gain value to generate the output signal, if no, there is no further step. Referring to FIG. 4B, a flowchart illustrating one embodiment of the step S34 of the audio playing method in the present invention is shown. As shown in FIG. 4B, in this embodiment, the step S34 comprises:
Step 341, comparing the background sound value with the critical value and generating a comparative result;
Step 342, adjusting the audio signal according to the comparative result and the gain value.
In the step S342, the audio signal is adjusted according to the gain value when the background sound value is larger than the critical value, and the audio signal will not be adjusted when the background sound value is lower than the critical value.

Referring to FIG. 4C, a flowchart illustrating another embodiment of the step S34 of the audio playing method in the present invention is shown. As shown in FIG. 4C, in another embodiment, the predetermined manner is to consult a reference table. In the embodiment, the step S34 comprises:
Step 343, storing a reference table in advance, wherein the reference table comprises a plurality of background sound values and a plurality of their respective corresponding gain values; and
Step 344, by consulting the reference table, the volume of the audio signal is adjusted to generate the output signal.

As discussed above, the audio playing apparatus and method in the present invention is to acquire sounds from background sounds at first, and to generate a corresponding audio signal based on the volume of the sound acquired from the background sounds, and then to adjust the playing volume based on the magnitude of the audio signal in order to meet the purpose of auto-adjusting the volume in accordance with background sounds. As a result, eliminating prior art inconveniences for the users concerning volume adjustment.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio playing apparatus, comprising:
a sound detecting module used for acquiring a sound from background sounds and generating a background sound signal;
a transforming module coupled to the sound detecting module for transforming a background sound signal to a background sound value;
a controlling module coupled to the transforming module for adjusting the volume of an audio signal according to a predetermined manner and the background sound value and generating an output signal; and
an output module coupled to the controlling module for playing the output signal.

2. An audio playing apparatus as claimed in claim 1, wherein the sound detecting module is a sensor used for acquiring the sound from background sounds and generating the background sound signal.

3. An audio playing apparatus as claimed in claim 1, wherein the transforming module comprises:
a filter used for filtering the background sound signal to generate a filtering signal;
an amplifier coupled to the filter for amplifying the filtering signal to generate an amplifying signal;
an analog-to-digital converter coupled to the amplifier for converting the amplifying signal to generate the background sound value.

4. An audio playing apparatus as claimed in claim 3, wherein the analog-to-digital converter converts an analog mode amplifying signal to a digital mode background sound value.

5. An audio playing apparatus as claimed in claim 1, wherein the predetermined manner is to predetermine a gain value, and the controlling module adjusts the volume of the audio signal according to the background sound value and the gain value and generates the output signal.

6 An audio playing apparatus as claimed in claim 1, wherein the predetermined manner is to predetermine a critical value and a gain value, and the controlling module determines whether the background sound value is larger than the critical value, and if yes, the controlling module adjusts the volume of the audio signal according to the gain value and generates the output signal.

7. An audio playing apparatus as claimed in claim 6, wherein the controlling module comprises:
a comparator used for comparing the background sound value with the critical value and generating a comparative result;
an adjuster coupled to the comparator and used for adjusting the audio signal according to the comparative result and the gain value,
wherein the adjuster adjusts the audio signal according to the gain value when the background sound value is larger than the critical value.

8. An audio playing apparatus as claimed in claim 1, wherein the controlling module comprises a reference table comprising a plurality of background sound values and a plurality of their respective corresponding gain values, and the predetermined manner is to consult the reference table, whereby the controlling module adjusts the volume of the audio signal and generates the output signal.

9. An audio playing apparatus as claimed in claim 1, wherein the output module comprises:
a digital-to-analog converter used for converting the output signal from digital mode to an analog mode;
an loudspeaker coupled to the digital-to-analog converter used for playing the output signal in the analog mode.

10. An audio playing method, comprising:
step (a), acquiring a sound of background sounds and generating a background sound signal;
step (b), transforming the background sound signal to generate a background sound value;
step (c), adjusting the volume of an audio signal according to a predetermined manner and the background sound value to generate an output signal; and
step (d) playing the output signal.

11. An audio playing method as claimed in claim 10, wherein the step (a) is to acquire the sound of the background sounds and generate the background sound signal with a sensor.

12. An audio playing method as claimed in claim 10, wherein the step (b) comprises:
step (b1), filtering the background sound signal to generate a filtering signal;
step (b2), amplifying the filtering signal to generate an amplifying signal; and
step (b3), converting the amplifying signal to generate the background sound value.

13. An audio playing method as claimed in claim 12, wherein the step (b3) is to convert an analog mode amplifying signal to a digital mode background sound value.

14. An audio playing method as claimed in claim 10, wherein the predetermined manner in the step (c) is to predetermine a gain value, and the step (c) is to adjust the volume of the audio signal according to the background sound value and the gain value and generate the output signal.

15. An audio playing method as claimed in claim 10, wherein the predetermined manner in the step (c) is to predetermine a critical value and a gain value, and the step (c) comprises:
step (c1), determining whether the background sound value is larger than the critical value; and
step (c2), if the result of the step (c1) is yes, adjusting the volume of the audio signal according to the gain value to generate the output signal.

16. An audio playing method as claimed in claim 10, wherein the step (c) comprises:
step (c3), comparing the background sound value with the critical value and generating a comparative result;
step (c4), adjusting the audio signal according to the comparative result and the gain value,
wherein the audio signal is adjusted according to the gain value when the background sound value is larger than the critical value.

17. An audio playing method as claimed in claim 10, wherein the predetermined manner in the step (c) is to consult a reference table, and the step (c) comprises:
step (c5), storing a reference table in advance, wherein the reference table comprises a plurality of background sound values and their respective corresponding gain value; and
step (c6), consulting the reference table to adjust the volume of the audio signal to generate the output signal.

18. An audio playing method as claimed in claim 10, wherein the step (d) comprises:
step (d1), converting the output signal from digital mode to an analog mode; and
step (d2), playing the output signal in analog mode with a loudspeaker.
